(19) United States
(12) Patent Application Publication
(10) Pub. No.: US 2009/0135656 A1
(43) Pub. Date: May 28, 2009

(54) NON-VOLATILE SEMICONDUCTOR MEMORY DEVICE WITH DUMMY CELLS AND METHOD OF PROGRAMMING THE SAME

(75) Inventor: Ki-Tae PARK, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/357,505

(22) Filed: Jan. 22, 2009

Related U.S. Application Data
(63) Continuation-in-part of application No. 11/947,007, filed on Nov. 29, 2007.

(30) Foreign Application Priority Data
Dec. 14, 2006 (KR) 10-2006-0127849
Jan. 22, 2008 (KR) 10-2008-0006431

(51) Int. Cl. G11C 16/06; G11C 29/00

(52) U.S. Cl. 365/185.19; 365/200; 365/185.2; 365/185.29

(57) ABSTRACT

A nonvolatile semiconductor memory device includes a memory cell array, an erase controller and a dummy cell controller. The memory cell array includes multiple cell strings, each including at least two dummy cells having different threshold voltages and normal memory cells. The erase controller performs, in cell block units, an erase operation for the normal memory cells of each cell string and an adjacent dummy cell of the at least two dummy cells positioned nearer the normal memory cells, and performs an erase verify operation for the normal memory cells. The dummy cell controller performs a program operation for each of the adjacent dummy cells within the memory cell array and a program verify operation of the adjacent dummy cells, and performs a program verify operation for remaining dummy cells, which are not adjacent dummy cells, and then a program operation for the remaining dummy cells requiring programming.

### CROSS-REFERENCE TO RELATED APPLICATIONS

A claim of priority is made to Korean Patent Application No. 10-2006-0127849, filed on Dec. 14, 2006, and to Korean Patent Application No. 10-2008-0006431, filed on Jan. 22, 2008, the subject matter of which are hereby incorporated by reference.

Further, the present application is a continuation-in-part of U.S. patent application Ser. No. 11/947,007, filed Nov. 29, 2007 (published as U.S. Patent Application Publication No. 2008/0144378), the subject matter of which is hereby incorporated by reference, which claims priority of Korean Patent Application No. 10-2006-0127849, filed on Dec. 14, 2006.

### SUMMARY OF THE INVENTION

The present invention relates to a semiconductor memory. More particularly, the present invention relates to a nonvolatile semiconductor memory having dummy cells.

Embodiments of the invention provide a nonvolatile semiconductor memory device capable of efficiently adjusting a threshold voltage of dummy cell performing a function different from a normal memory cell. A program operation for dummy cells can be performed relatively faster and more efficiently.

Embodiments of the invention provide a method for programming dummy cells more efficiently and relatively faster in a nonvolatile semiconductor memory device, which includes dummy cells within a cell string, to prevent or substantially reduce read error caused by read disturbances. Also, electrical stress may be reduced during a read operation.

Embodiments of the invention provide a method for efficiently die-sorting and repairing semiconductor memory chips at a wafer level after fabricating on a wafer multiple semiconductor memory chips, each having at least one dummy cell within a cell string.

Embodiments of the invention provide a nonvolatile semiconductor memory device and a method for more efficiently treating at least one dummy cell adapted within a cell string of a nonvolatile semiconductor memory device.

Embodiments of the invention provide a method for programming in a shorter time, dummy cells functioning as a floating formation switching unit in a NAND-type nonvolatile semiconductor memory device, which is capable of preventing read disturbances by maintaining boosted-channel voltage of non-selected memory cell transistors in a non-selected cell string in a read operation.

According to an embodiment of the invention, a method is provided for die-sorting and repairing semiconductor memory chips on a wafer, each of the semiconductor memory chips having at least one dummy cell within a cell string. The method includes adjusting a threshold voltage for the at least one dummy cell within the cell string, and performing die-sorting and repair of normal memory cells within the cell string.

The method may further include performing die-sorting and repair of the at least one dummy cell before completing the adjusting of the threshold voltage for the at least one dummy cell. Also, the threshold voltage for the at least one dummy cell may be adjusted in response to an applied special command different from a normal command.

According to another embodiment of the invention, a nonvolatile semiconductor memory device includes a memory cell array on a semiconductor memory chip and a dummy cell controller. The memory cell array includes at least two dummy cells, having different threshold voltages, and multiple normal memory cells within a cell string. The dummy cell controller is configured to adjust the threshold voltages of the dummy cells in response to an input command before performing a die-sorting and repair operation for the normal memory cells, in die-sorting and repairing the semiconductor memory chip at a wafer level. The wafer is fabricated to include multiple semiconductor memory chips.

The dummy cell controller may further perform a die-sorting and repair operation before adjusting the threshold voltages of the dummy cells.

According to another embodiment of the invention, a method is provided for programming dummy cells before post programming normal memory cells in a semiconductor memory device, where the semiconductor memory device includes a memory cell array including multiple cell strings. Each cell string includes at least two dummy cells with different threshold voltages and multiple normal memory cells. The method includes performing an erase operation for the normal memory cells of each cell string by a cell block unit and for an adjacent dummy cell of the at least two dummy cells, the adjacent dummy cell being closest to the normal memory cells in the cell string, and then performing an erase verify operation for the normal memory cells. A program operation and a program verify operation are preformed for the adjacent dummy cell in each cell string of the memory cell array. A program verify operation is performed for a remaining dummy cell of the at least two dummy cells in each cell string, and then a program operation is performed for the remaining dummy cell when the remaining dummy cell requires programming.

The remaining dummy cell is positioned closer to a ground selection line of the cell string than the adjacent dummy cell. In the erase operation of each cell string, a voltage equal to an erase gate voltage, applied to a gate of each of the normal memory cells, may be applied to a gate of the adjacent dummy cell, and one of a floating voltage or a voltage higher than the erase gate voltage may be applied to a gate of the remaining dummy cell. In the erase verify operation of each cell string, one of a ground voltage or a read voltage may be applied to the gate of the adjacent dummy cell, and the read voltage may be applied to the gate of the remaining dummy cell.

A step increasing width of incremental step-pulse programming used in the program operation of the dummy cells may be predetermined to be greater than a step increasing width of incremental step-pulse programming used in a program operation of the normal memory cells.

The program operation of the adjacent dummy cells may be performed in response to an external input command.

When there are two dummy cells in each cell string, the adjacent dummy cell may be coupled to a normal memory cell positioned farthest from a corresponding bit line and the remaining dummy cell may be coupled to a ground selection transistor. When there are three dummy cells in each cell string, the adjacent dummy cell may be coupled to a normal memory cell positioned farthest from a bit line, and the remaining dummy cells may be respectively coupled to a ground selection transistor and a string selection transistor.

According to another embodiment of the invention, a nonvolatile semiconductor memory device includes a memory cell array, an erase controller and a dummy cell controller. The memory cell array includes multiple cell strings, each cell string including at least two dummy cells having different threshold voltages and normal memory cells. The erase controller is configured to perform, in cell block units, an erase operation for the normal memory cells of each cell string and an adjacent dummy cell of the at least two dummy cells positioned nearer the normal memory cells, and to perform an erase verify operation for the normal memory cells. The dummy cell controller is configured to perform a program operation for each of the adjacent dummy cells within the memory cell array and a program verify operation of the adjacent dummy cells, and to perform a program verify operation for remaining dummy cells, which are not adjacent dummy cells, and then a program operation for the remaining dummy cells requiring programming.

The erase controller may apply the same voltage as an erase gate voltage, applied to the normal memory cells, to a gate of the adjacent dummy cell in erasing the normal memory cells, and may apply one of a floating voltage or voltage higher than the erase gate voltage to a gate of remaining dummy cells, to prevent a change of threshold voltage for the dummy cells. Also, in the erase verify operation, the erase controller may apply one of a ground voltage or a read voltage to a gate of the adjacent dummy cell, and apply the read voltage to a gate of the remaining dummy cells.

The dummy cell controller may determine a step increasing width of an incremental step-pulse program used in the program operation of the dummy cells, higher than that of normal memory cell. Further, the dummy cell controller may perform the program operation of the dummy cells in response to a mode register set signal.

When the cell string includes two dummy cells, the adjacent dummy cell is coupled to a normal memory cell positioned farthest from a bit line, and the remaining dummy cell is coupled to a ground selection transistor. The remaining dummy cells requiring the program operation may be cells having a threshold value lower than a predetermined threshold voltage. When the program operation for the remaining dummy cells is completed, a post program for the normal memory cells may be performed.

According to another embodiment of the invention, a nonvolatile semiconductor memory device includes a memory cell array, an erase control circuit and a dummy cell control circuit. The memory cell array includes multiple strings, each cell string including a first selection transistor having a drain coupled to a bit line, a second selection transistor having a source coupled to a common source line, multiple memory cell transistors respectively having channels coupled in series to a source of the first selection transistor and floating gates, and third and fourth selection transistors respectively having channels coupled in series between a source of the last memory cell transistor among the memory cell transistors and a drain of the second selection transistor and having mutually different threshold voltage values. The erase control circuit is configured to perform, in cell block units, an erase operation for the memory cell transistors and the third selection transistor, and then to perform an erase verify operation for the memory cell transistors. The dummy cell control circuit is configured to perform a program operation and a program verify operation for all the third selection transistors within the memory cell array, and to first perform a program verify operation for all the fourth selection transistors within the memory cell array and then to perform a program operation for the fourth selection transistors requiring programming.

In various schematic and methodic configurations, program operations for dummy cells are performed faster and more efficiently, for example, thereby reducing manufacturing costs of nonvolatile semiconductor devices and increasing programming convenience. In addition, the functionality of dummy cells is effectively guaranteed and reliability in nonvolatile semiconductor memory device operation is enhanced.

### BRIEF DESCRIPTION OF THE DRAWINGS

The embodiments of the present invention will be described with reference to the attached drawings, in which:

FIG. 1 is a block diagram of nonvolatile semiconductor memory device;

FIG. 2A is a circuit diagram of an equivalent circuit illustrating a connected structure of memory cells in a memory cell array of FIG. 1;

FIG. 2B illustrates an example of bias voltage applied to the equivalent circuit of FIG. 2A in a read operating mode;

FIG. 3 illustrates related-voltage stress in respective memory cells connected to selected-bit line and non-selected bit line, for example, of FIG. 2B;

FIG. 4 illustrates a connected structure of memory cell strings, according to exemplary embodiments of the present invention;

FIG. 5 is a circuit diagram of an equivalent circuit illustrating an embodiment of FIG. 4;

FIG. 6 illustrates a related read operation bias voltage applied to the equivalent circuit of FIG. 5;

FIG. 7 is a circuit diagram of an equivalent circuit illustrating another embodiment of FIG. 4;

FIG. 8 illustrates voltage stress in a non-selected memory cell of FIG. 4;

FIG. 9 illustrates a simulation showing a channel voltage boosting effect to prevent a read disturbance in the exemplary embodiments of FIG. 4;

FIG. 10 is a block diagram of nonvolatile semiconductor memory device, according to exemplary embodiments of the present invention;

FIG. 11 is a circuit diagram of an equivalent circuit illustrating cell string structures having two or more dummy cells per cell string within the memory cell array shown in the exemplary embodiments of FIG. 10;

FIG. 12 is a flowchart illustrating a related sequence of die-sorting and repair for dummy cells and normal memory cells when fabrication of the device of FIG. 10 onto a wafer is complete, according to exemplary embodiments of the present invention;

FIG. 13 illustrates a related bias voltage of erase operation in a block erase of memory cells of FIG. 11;

FIG. 14 is a flowchart providing a sequence of program operations for dummy cells and a block erase operation referred to in FIG. 13;

FIG. 15 illustrates a distribution change of threshold voltage for cell transistors according to an operation sequence of FIG. 14;

FIG. 16 is a table illustrating a related operation bias voltage individually applied according to the operation sequence of FIG. 14; and

FIG. 17 illustrates a comparison of step increasing widths of incremental step-pulse programs for dummy cell and normal cell in a program operation of FIG. 14.

### DETAILED DESCRIPTION OF THE EMBODIMENTS

Embodiments of the present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

Unless otherwise defined, all terms (including technical and scientific terms) used herein have the same meaning as commonly understood in the art to which this invention belongs. It is further understood that terms used herein should be interpreted as having a meaning that is consistent with their meaning in the context of this specification and the relevant art, and should not be interpreted in an idealized or overly formal sense unless expressly so defined herein. Exemplary embodiments of the present invention are more fully described below with reference to the accompanying drawings. This invention may, however, be embodied in many different forms and should not be construed as being limited to the exemplary embodiments set forth herein. Rather, these exemplary embodiments are provided so that this disclosure is thorough and complete, and conveys the concept of the invention to those skilled in the art.

Recent rapid developments in information processing devices have tended to increase the need for higher speed operations and larger storage capacities in semiconductor memory devices used as components within the information processing devices. Typically semiconductor memory devices are classified as volatile semiconductor memory devices or nonvolatile semiconductor memory devices.

A volatile semiconductor memory device may be classified as a dynamic random access memory or a static random access memory. A volatile semiconductor memory device has fast read and write speeds. However, contents stored in memory cells of the volatile semiconductor memory device are lost when external power supply is cut off.

A nonvolatile semiconductor memory device may be classified as a mask read only memory (MROM), a programmable read only memory (PROM), an erasable programmable read-only memory (EPROM), an electrically erasable programmable read-only memory (EEPROM), etc. Such nonvolatile semiconductor memory devices have been typically used to store contents that must be preserved even when external power is removed because nonvolatile memories can permanently keep contents within memory cells, regardless of power. However, with respect to the MROM, PROM and EPROM, general users are not free to execute erase and write (or program) operations using the electronic system itself. In other words, it is difficult to erase or re-program programmed-contents in an on-board state. In contrast, an EEPROM may be used in a system program storage device or auxiliary storage device, which needs its contents continuously updated, because erase and write operations are validated by the system itself.

Many electronic devices controlled by a computer or micro-processor incorporate EEPROMs due to their high density and electrically erasable and programmable capabilities. Moreover, a data storage device, such as a digital camera etc., must be compact in the size. However, a hard disk device having a rotary magnetic disk and being used as an auxiliary memory device in a battery-powered computer system, such as a portable computer or notebook computer, needs to occupy a relatively large space. Therefore, designers of these systems are typically interested in EEPROMs, which occupy a relatively small area and have a relatively high density and performance.

A flash EEPROM, e.g., having a flash erase function, has been developed as advancements have been made in EEPROM design and manufacturing technology. A flash EEPROM has a higher integration level than a general EEPROM, and is desirable for use as a large-capacity auxiliary memory device. The flash EEPROM is classified as a NAND, NOR or AND type depending on the corresponding type of unit memory cell arrays. It is well known that the NAND type flash EEPROM has a higher integration level than the NOR or AND types.

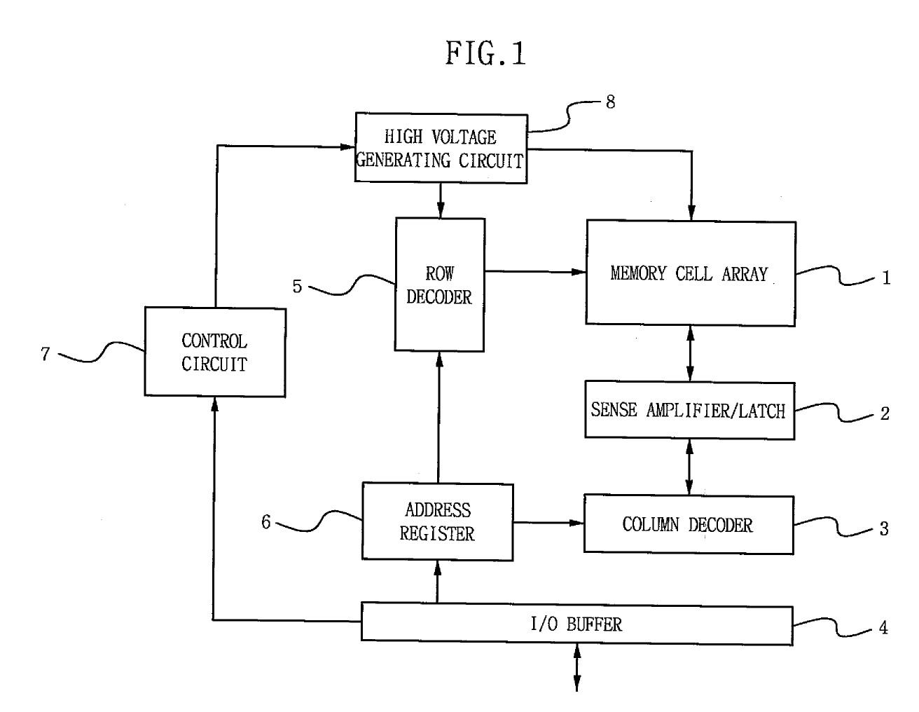

FIG. 1 is a block diagram of a nonvolatile semiconductor memory device. FIG. 1 illustrates configuration of blocks of a NAND-type EEPROM, including a memory cell array 1, a sense amplifier and latch 2 for sensing and storing input/output data of memory cell transistors, a column decoder 3 for selecting bit lines, an input/output buffer 4, a row decoder 5 for selecting word lines, an address register 6, a high voltage generating circuit 8 for generating a high voltage higher than a power supply voltage, and a control circuit 7 for controlling operation of a memory device.

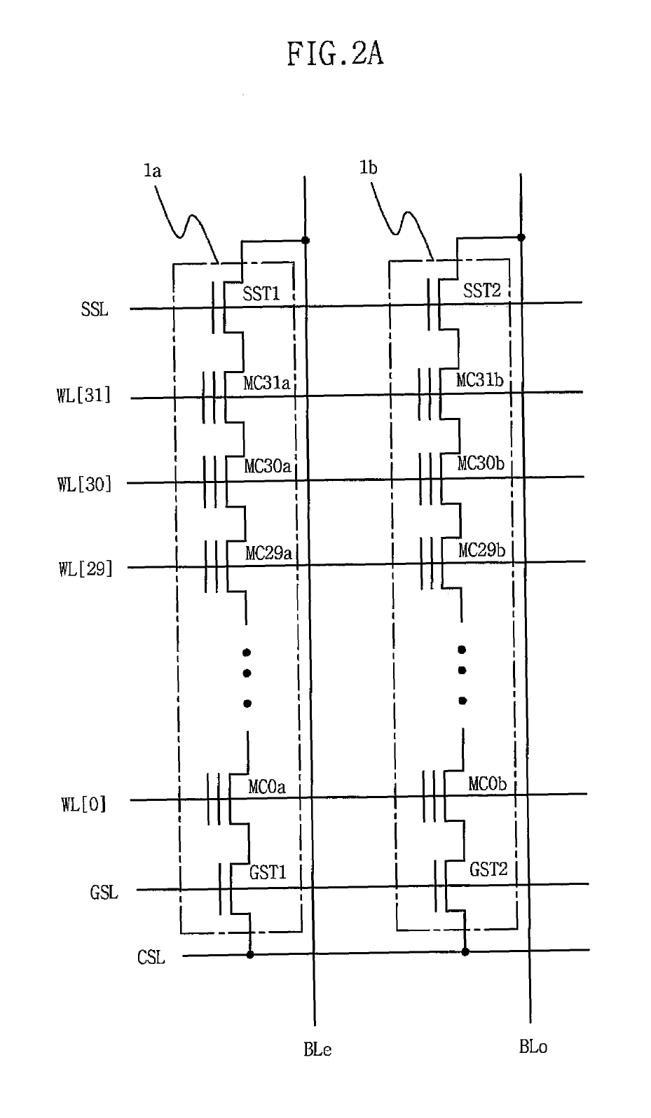

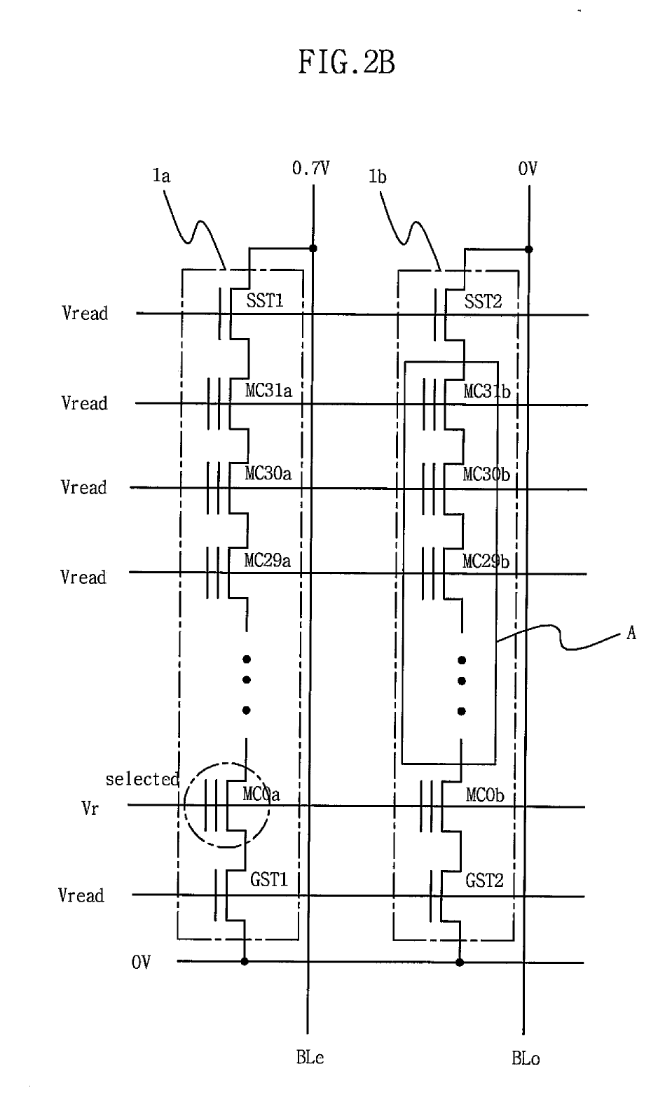

FIG. 2A is a circuit diagram of an equivalent circuit illustrating the structure of memory cells within the memory cell array 1 of FIG. 1. The memory cell array 1 actually includes multiple cell strings or NAND cell units, but for convenience of explanation, FIG. 2A shows only a first cell string 1a coupled to an even bit line BLe and a second cell string 1b coupled to an odd bit line BLo.

The first cell string 1a includes a string selection transistor SST1 having a drain coupled to a bit line BLe, a ground selection transistor GST1 having a source coupled to a common source line CSL, and multiple memory cell transistors MC31a, MC30a, . . . , MC0a having drain-source channels connected in series between a source of the string selection transistor SST1 and a drain of the ground selection transistor GST1.Similarly, the second cell string 1b includes a string selection transistor SST2 having a drain coupled to bit line BLo, a ground selection transistor GST2 having a source coupled to common source line CSL, and multiple memory cell transistors MC31b, MC30b, . . . , MC0b having drain-source channels connected in series between a source of the string selection transistor SST2 and a drain of the ground selection transistor GST2.

A signal applied to a string selection line SSL is supplied in common to gates of the string selection transistors SST1 and SST2, and a signal applied to a ground selection line GSL is supplied in common to gates of the ground selection transistors GST1 and GST2. Word lines WL0-WL31 are individually coupled equivalently in common to control gates of memory cell transistors on the same row. The bit lines BLe and BLo, which are operationally connected to the sense amplifier and latch 2 of FIG. 1, run perpendicular to and on a different layer different from the word lines WL0-WL31. The bit lines BLe and BLo are parallel with one another on the same layer.

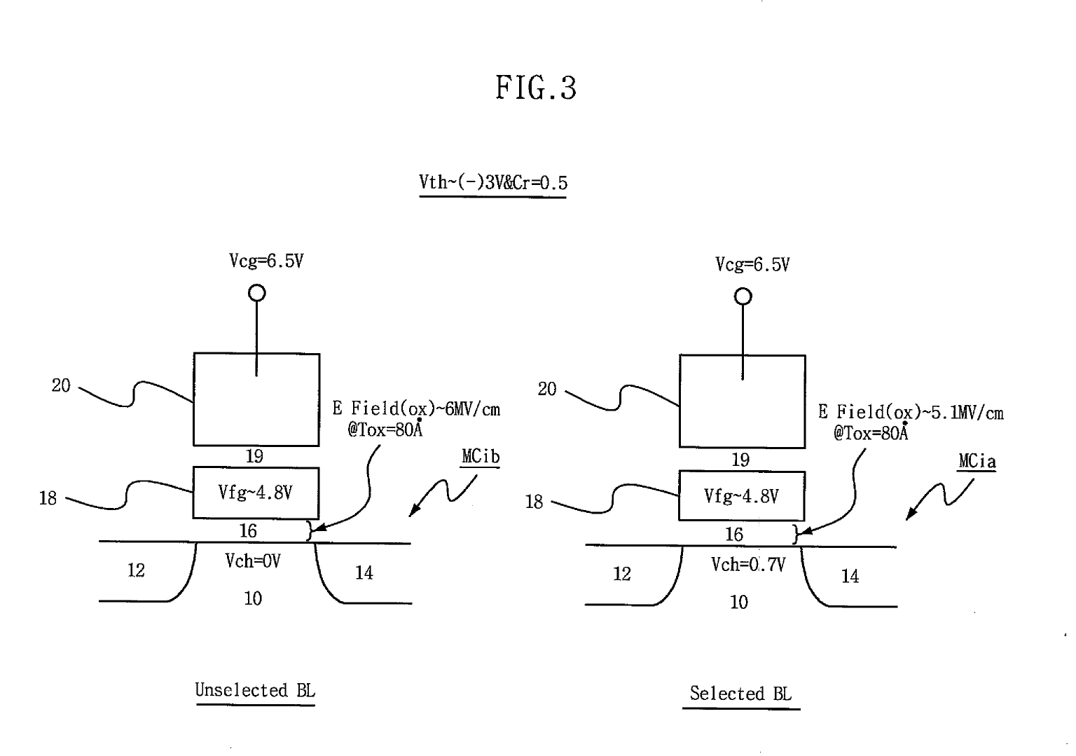

Erase, write and read operations of the NAND type EEPROM are generally performed as follows. The erase and program or write operations are performed using known F-N tunneling current. For example, in the erase operation, a very high potential is applied to substrate 10 shown in FIG. 3, and a relatively low potential is applied to a CG (Control Gate 20) of memory cell transistor. In this case, a potential determined by a coupling ratio of a capacitance between CG and FG (Floating Gate 18) and a capacitance between FG and the substrate is applied to the FG 18. When a potential difference between a floating gate voltage Vfg applied to the FG 18 and a substrate voltage Vsub applied to the substrate 10 is greater than a potential difference creating F-N tunneling, electrons gathered on the FG 18 move to the substrate 10. This operation lowers a threshold voltage Vt of a memory cell transistor which includes CG 20, FG 18, source 12 and drain 14. The Vt is sufficiently lowered, so that, even though 0V is applied to CG 20 and source 12, current flows when an appropriate amount of voltage is applied to the drain 14. This may be called “ERASED,” and is logically represented as “1”.

Meanwhile, in the write operation, 0V is applied to source 12 and drain 14, and a very high voltage is applied to CG 20. At this time, an inversion layer is formed in a channel region and the source 12 and the drain 14 both have a potential of 0V. When a potential difference applied to between Vchannel (0 V) and Vfg, determined by a ratio of capacitances between CG 20 and FG 18 and between FG 18 and the channel region, becomes great enough to create the F-N tunneling, electrons move from the channel region to the FG 18. When Vt increases, a predetermined amount of voltage is applied to the CG 20, 0V is applied to the source 12, and an appropriate amount of voltage is applied to the drain 14, current does not flow. This may be called “PROGRAMMED,” and is typically represented as logic “0”.

In a memory cell array having multiple cell strings, such as the first and second cell strings 1a and 1b, page units indicate memory cell transistors in which control gates are connected in common to the same word line. Multiple pages, including memory cell transistors, are provided as a cell block. One cell block unit generally includes one or more cell strings per bit line. NAND flash memory has a page program mode for a high-speed programming. A page program operation is classified as a data loading operation and program operation. The data loading operation sequentially latches and stores data of a byte size provided from input/output terminals at data registers. The data registers correspond to respective bit lines. The program operation writes at a time data stored in the data registers to memory transistors on a word line selected through bit lines.

In the NAND-type EEPROM described above, read and program operations are generally performed by page units, and an erase operation is performed by block units. Actually, electron movement between a channel and FG of the memory cell transistor appears only in program and erase operations. In read operations, data stored in a memory cell transistor are just read intact without damaging the data after completion of the program and erase operations.

In the read operation, a voltage, generally a read voltage, higher than selection read voltage Vr applied to a CG of a selected memory cell transistor, is supplied to a CG of a non-selected memory cell transistor. Then, current flows or does not flow on a corresponding bit line according to a program state of the selected-memory cell transistor. When a threshold voltage of the programmed memory cell is higher than a reference value in a predetermined voltage condition, the memory cell is determined to be an off-cell, thus charging a corresponding bit line to a high level voltage. To the contrary, when the threshold voltage of a programmed memory cell is lower than the reference value, the memory cell is determined to be an on-cell, and a corresponding bit line is discharged to a low level. The state of the bit line is finally read out as “0” or “1” through a sense amplifier called the page buffer.

Memory cell transistors within the cell string have an erase operation to initially have a threshold voltage under about −3V, for example. Then, when a high voltage is applied to a word line of a selected memory cell for a given time to program the memory cell transistor, the selected memory cell is changed to having a higher threshold voltage, while threshold voltages of non-selected memory cells are not changed.

FIG. 2B illustrates an example of bias voltage applied to the equivalent circuit of FIG. 2A in a read operating mode, i.e., for performing a read operation. For example, when the even-bit line BLe is selected during a read operation, an applied precharge voltage of 0.7V, for example, is applied to the selected even bit line BLe and a noise shielding voltage of 0V, for example, is applied to the non-selected odd bit line BLo. In this case, when a memory cell transistor MC0a of the first cell string 1a is selected, a selection read voltage Vr is applied to selected word line WL0, and a read voltage Vread is applied to the non-selected word lines WL1-WL31, the string selection line SSL and the ground selection line GSL. Further, 0V is applied to a common source line CSL.

Data stored in memory cell transistor MC0a of the selected first cell string 1a is sensed and a read operation is performed, based on the voltage bias described above. More particularly, when the string selection transistor SST1, the ground selection transistor GST1 and the memory cell transistors MC01-MC31a are turned ON, the voltage of selected bit line BLe is discharged to a level of 0V or a determined voltage is maintained nearly intact, according to a threshold voltage value of the memory cell transistor MC0a. When a threshold voltage of the selected memory cell transistor is lower than a reference value, a current path from the selected bit line BLe to the common source line CSL is formed and so the selected bit line BLe is discharged to a lower level. Thus, the sense amplifier connected to the selected bit line BLe senses a selected memory cell transistor as an on-cell, data “0” or “1”. When electrons are injected into a floating gate of the selected memory cell, such that a threshold voltage is higher than a reference value, a current path from the selected bit line BLe to the common source line CSL is not formed, so voltage precharged to the selected bit line BLe is maintained at almost its level state. At this time, the sense amplifier connected to the selected bit line BLe senses a selected memory cell as an off-cell, data “1” or “0”.

In the read operating mode described above, the read voltage Vread is also applied to control gates of memory cell transistors MC31b, MC30b, . . . , MC1b, provided in second cell string 1b coupled to non-selected bit line BLo. In other words, the non-selected memory cell transistors MC31b, MC30b, . . . , MC1b:A have electrical stress. A read disturbance is caused by the electrical stress, as discussed in reference to FIG. 3.

FIG. 3 shows related-voltage stress in respective memory cells connected to a selected-bit line and a non-selected bit line, for example, as shown in FIG. 2B. In the drawing on the left in FIG. 3, a memory cell transistor MCib indicates any one of the non-selected memory cell transistors MC31b, MC30b, . . . , MC1b:A in the second cell string 1b of FIG. 2B. In the drawing on the right in FIG. 3, a memory cell transistor MCia indicates any one of the non-selected memory cell transistors MC31a, MC30a, . . . , MC1a connected to the selected bit line BLe of FIG. 2B.

For example, it may be assumed that a threshold voltage of a memory cell transistor is about −3V and a coupling ratio indicating a rate of capacitance is about 0.5, the rate of capacitance corresponding to an interlayer dielectric layer 19, such as ONO, etc., formed in a lower part of a control gate 20, and a gate insulation layer 16, such as a gate oxide layer, etc., formed in a lower part of a floating gate 18. It may be further assumed that a thickness of the gate insulation layer 16 is about 80 Å and an applied read voltage Vread of the control gate 20 is about 6.5V. Based on these assumptions, a drain-source channel voltage of the memory cell transistor MCib is lower than a drain-source channel voltage of the memory cell transistor MCia by 0.7V. Therefore, a relatively strong electric field operates in the gate insulation layer 16, causing electrical stress. For example, the electrical field applied to the gate insulation layer 16 of the memory cell transistor MCib is about 6 MV/cm, and the electrical field applied to the gate insulation layer 16 of the memory cell transistor MCia is about 5.1 MV/cm.

As illustrated in FIG. 3, the memory cells receiving the most electrical stress in a general read operating mode are the non-selected memory cell transistors MCib connected to a bit line to which 0V is applied (the Non-selected BL) in order to serve as a noise shielding for an adjacent bit line. Channel voltages of non-selected memory cells MCia connected to the selected bit line BL are maintained at 0.5V to 0.7V, so a read disturbance is relatively less.

As described above, in a read operation, non-selected memory cell transistors connected to a non-selected bit line have relatively high electrical stress due to low channel voltage. The electrical stress increases the probability of causing read disturbances, especially in highly integrated memories. For example, as a gate oxide layer (e.g., a gate insulation layer) becomes thinner and a distance between a lower part of a control gate and an active region becomes narrower, the electrical stress may incrementally shift a threshold voltage value of a memory cell transistor. As a result, when the memory cell transistor undergoing a shifted threshold voltage value in a read operating mode is selected, read error may be caused by the read disturbance.

Moreover, a memory cell region of a flash EEPROM, in which a read operation is mainly performed, may have a small quantity of code data, such as ROM table information, that requires high speed access or indexing information for stored data of a main memory cell array, etc. When a read disturbance occurs during a read operation in memory cells belonging to the memory cell region, it may be very serious. When a read error occurs due to read disturbance, causing a variation of threshold voltage of memory cells, the data affected by the read error may be difficult to recover to a normal state, even using error correction code logic, etc., thus causing an overall defect of in memory device.

Therefore, to substantially reduce a read disturbance in a nonvolatile semiconductor memory, a floating formation switching unit, which maintains a channel voltage of memory cells coupled to a non-selected bit line at a level above a power supply voltage, is included within a memory cell array.

The floating formation switching unit is provided in every cell string of the memory cell array, and includes a switching transistor as a dummy cell connected between a ground selection transistor and a memory cell positioned farthest from a bit line among the memory cells of each cell string. To serve the dummy cell adapted within the cell string as the floating formation switching unit, a threshold voltage of the dummy cell must be adjusted at a desired determination level.

As described above, a dummy cell is employed not only to prevent a read disturbance, but also to store information for memory chips or to store a small quantity of code data, such as indexing information etc., for storing data of memory cell array. A threshold voltage adjusting for dummy cells may be performed differently from a normal memory cell.

The threshold voltage adjusting operation for dummy cells must be performed efficiently and relatively quickly to enhance reliability of semiconductor memory devices in mass production.

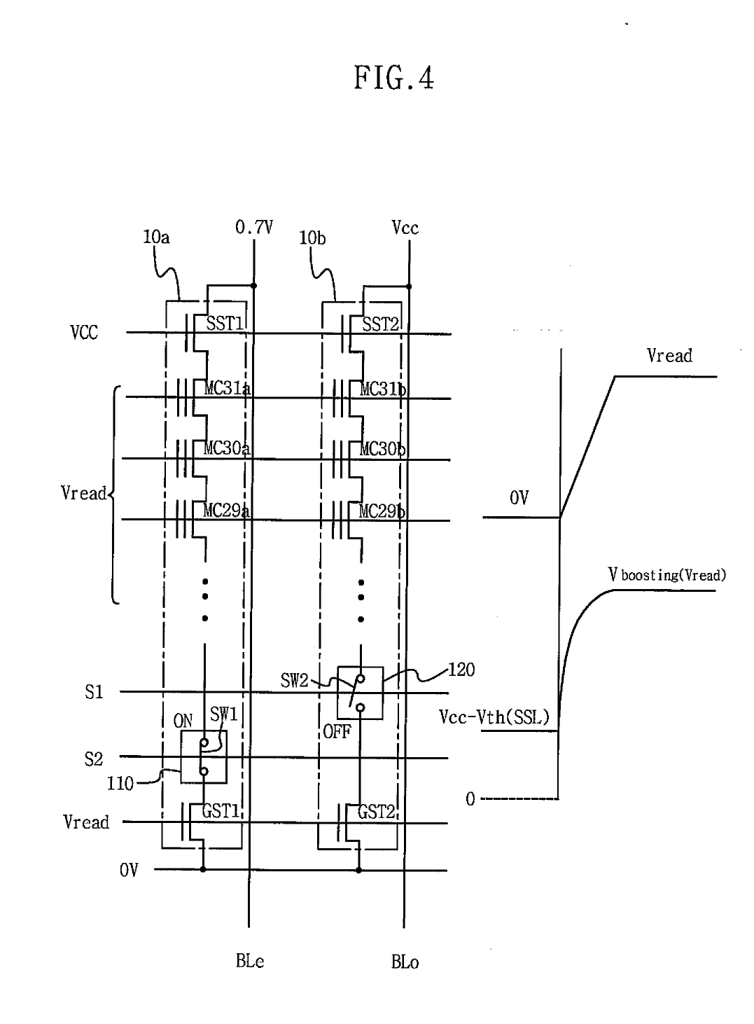

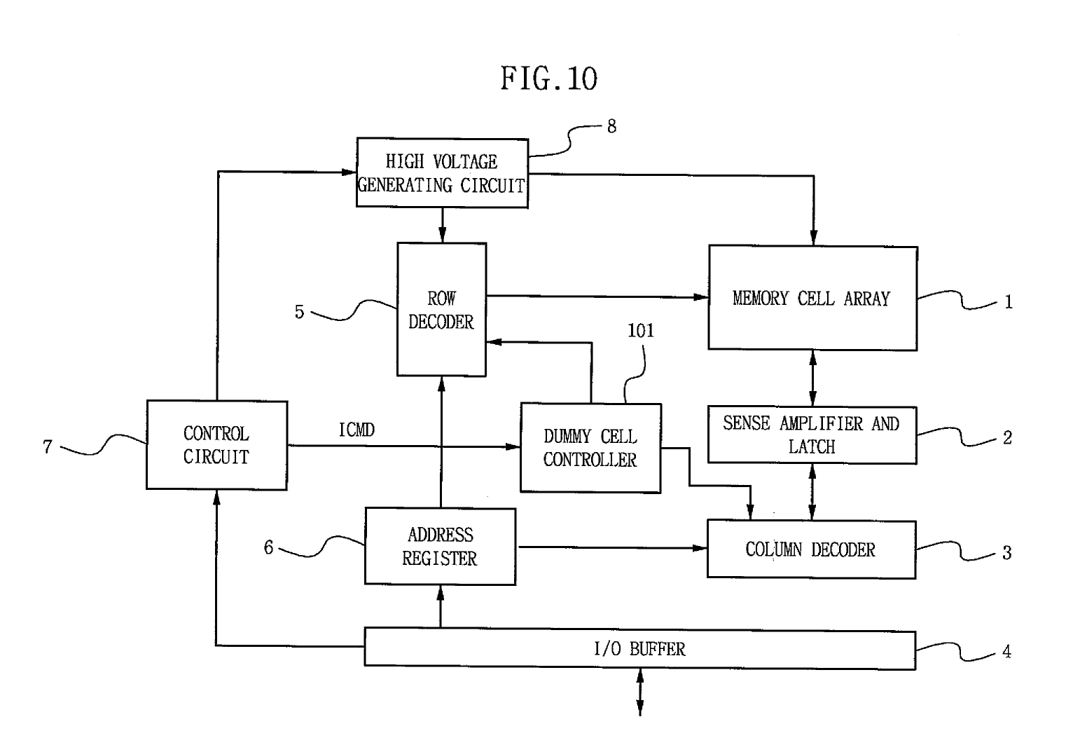

According to various embodiments of the present invention, function and operation of dummy cells as floating formation switching units to prevent read disturbance are described with reference to FIGS. 4 to 9. In addition, a threshold voltage adjusting technology for efficiently performing threshold voltage adjustment for dummy cells more rapidly, according to various embodiments, is described with reference to FIGS. 10 to 17.

FIG. 4 illustrates a connected structure of memory cell strings according to various embodiments of the present invention. The memory cell strings are in a memory cell array, which may be incorporated into a nonvolatile semiconductor memory device having other operational elements, such as the sense amplifier/latch 2 and the control circuit 7, for example, as shown in FIG. 1.

Referring to FIG. 4, floating formation switching units 10 and 120 are provided within cell strings 10a and 10b to increase a drain-source channel voltage of non-selected memory cells within a non-selected cell string on a self-boosting operating principle. In the read operation mode, a relatively high voltage Vcc is applied as a precharge voltage for self-boosting to non-selected bit line BLo. A switch SW2 of the floating formation switching unit 120 is turned OFF, so common source line CSL is electrically isolated from the cell string 10b.

Referring to FIG. 4, an interior connection structure of cell strings constituting a memory cell array for comparison to FIG. 2A. Cell strings 10a and 10b include floating formation switching units 110 and 120, respectively. The floating formation switching unit (e.g., 110 or 120) belonging to a non-selected cell string (e.g., 10a or 10b) during a read operating mode operates so that a channel voltage of each of the memory cells connected to a non-selected bit line is maintained at a level above a power supply voltage. In other words, a floating formation switching unit is included in every cell string of the memory cell array. The floating formation switching unit is switched ON when the bit line corresponding to the cell string is selected and switched OFF when the bit line corresponding to the cell string is not selected.

For example, FIG. 4 depicts when an odd bit line BLo is not selected, in which case a power supply voltage Vcc is applied to the odd bit line BLo, and the switch SW2 of the floating formation switching unit 120 in the cell string 10b is switched to the OFF position by a control voltage S1.FIG. 4 further depicts when an even bit line BLe is selected, in which case a voltage 0.7V is applied to the even bit line BLe, and the switch SW1 of the floating formation switching unit 110 in the cell string 10a is in the ON position.

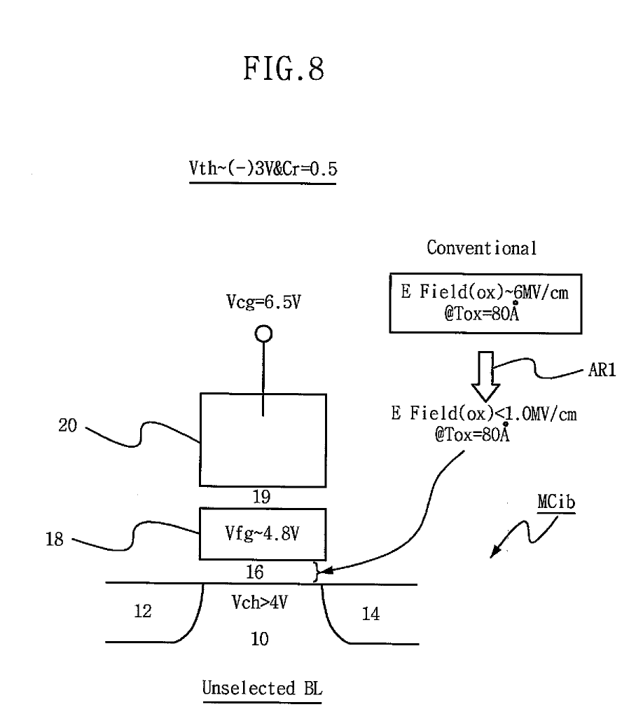

When the floating formation switching unit 120 is switched OFF, a common source line CSL is electrically separated from the second cell string 10b. At this time, a channel of each non-selected memory cell transistors MC31b, MC30b, . . . , MC1b is in a state of having been precharged to a channel voltage corresponding to VCC-Vth (the threshold voltage of SST2), as shown in the lower graph in FIG. 4. When the read voltage Vread is applied to the control gates of the non-selected memory cell transistors MC31b, MC30b, . . . , MC1b, e.g., after the floating formation switching unit 120 is switched OFF, the channel voltage increases by a self-boosting operation of the memory cell transistors, as shown in the lower graph. The voltage Vboosting, increased by the self-boosting, depends on a coupling ratio of the memory cell transistors, and is provided as a voltage level over about 4V. Electrical stress applied to a gate insulation layer 16 of the non-selected memory cell transistors MC31b, MC30b, . . . , MC1b, i.e., electric field, drops below about 1.0MV/cm, as shown in FIG. 8. Accordingly, the electrical stress applied to the non-selected memory cell transistors MC31b, MC30b, . . . , MC1b is significantly weakened, as compared to the electrical stress applied to the non-selected memory cell transistors connected to the selected bit line, thereby substantially reducing or preventing read disturbance.

In FIG. 4, although it was assumed that the odd bit line BLo was not selected, it may be assumed alternatively that the even bit line BLe is not selected, in which case the power supply voltage Vcc is applied to the even bit line BLe in a read operating mode, and a voltage of 0.7V is applied to the odd bit line BLo. At this time, the ON/OFF operation of the switches SW1 and SW2 becomes the opposite of that depicted in FIG. 4. That is, the switch SW1 is OFF and the switch SW2 is ON.

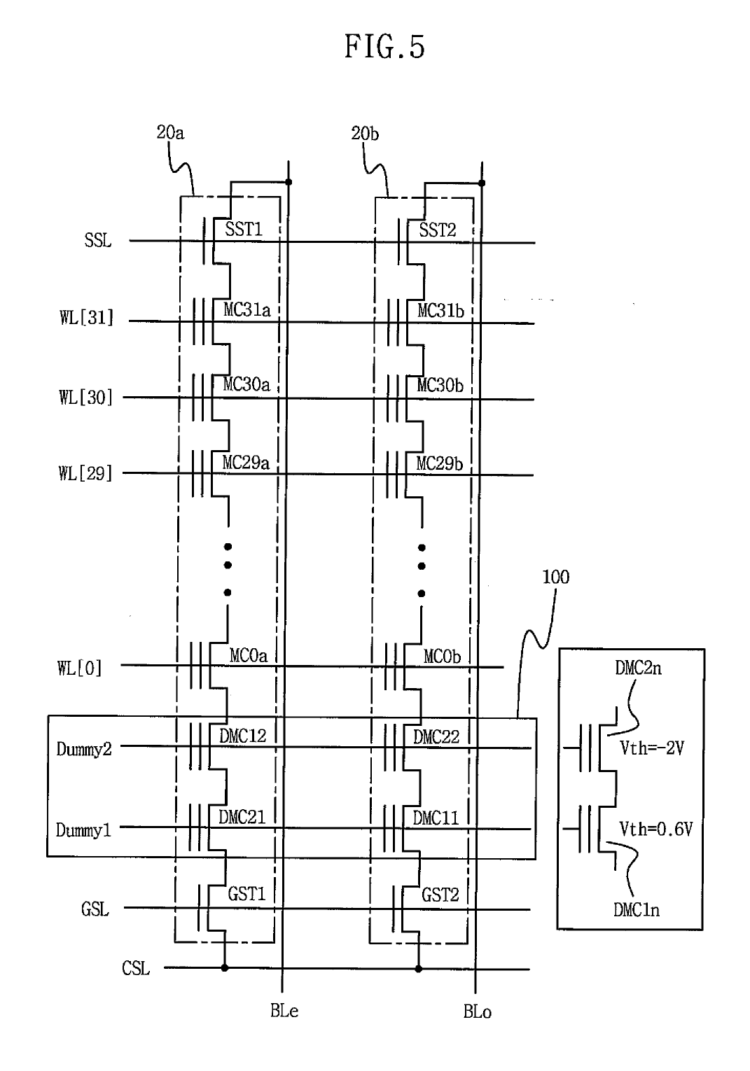

FIG. 5 is a circuit diagram of an equivalent circuit for an embodiment of FIG. 4. With reference to FIG. 5, a first cell string 20a includes a first selection transistor SST1 having a drain connected to a bit line BLe, a second selection transistor GST1 having a source coupled to a common source line CSL, memory cell transistors MC31a, MC30a, MC0a having channels connected in series to a source of the first selection transistor SST1, and third and fourth selection transistors DMC12 and DMC21 having channels connected in series to each other between a source of a last memory cell transistor MC0a and a drain of the second selection transistor GST1. The third and fourth selection transistors DMC12 and DMC21 have different threshold voltage values. Also, each of the memory cell transistors MC31a, MC30a, . . . MC0a has a floating gate.

Similarly, a second cell string 20b includes a first selection transistor SST2 having a drain connected to the bit line BLo, a second selection transistor GST2 having a source coupled to the common source line CSL, memory cell transistors MC31b, MC30b, . . . , MC0b having channels connected in series to the source of the first selection transistor SST2, and third and fourth selection transistors DMC22 and DMC11 having channels connected in series to each other between a source of a last memory cell transistor MC0b and a drain of the second selection transistor GST2. The third and fourth selection transistors DMC22 and DMC11 have different threshold voltage values. Also, each of the memory cell transistors MC31b, MC30b, . . . , MC0b has a floating gate.

In a dummy cell unit 100, which constitutes the floating formation switching units (e.g., 110 and 120 of FIG. 4), the dummy cell transistors DMC11 and DMC12 are determined to have a threshold voltage of about 0.6V, and the dummy cell transistors DMC21 and DMC22 are determined to have a threshold voltage of about −2V. When the second cell string 20b is not selected, a control voltage Dummy2 is applied as read voltage Vread, and a control voltage Dummy1 is applied as about 1V, and thus the dummy cell transistor DMC22 is turned ON and the dummy cell transistor DMC11 is turned OFF. Thus, the common source line CSL is not electrically connected to the bit line BLo through the second cell string 20b. On the other hand, the dummy cell transistors DMC12 and DMC21 in the selected cell string 20a are both turned ON, and thus enable a normal read operation for a selected memory cell transistor in the first cell string 20a.

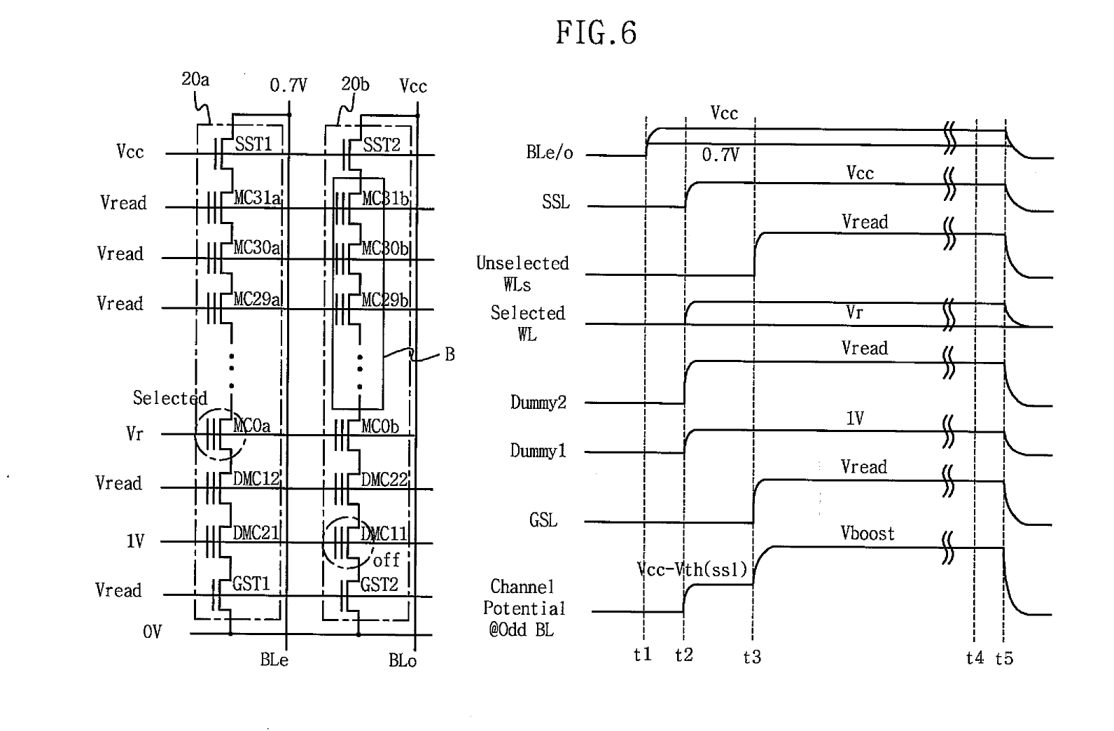

With reference to FIG. 6 illustrating a related read operation bias voltage applied to the equivalent circuit of FIG. 5, channel voltage for non-selected memory cells connected to a non-selected bit line increases by self-boosting.

For example, when in the dummy cell unit 100 of FIG. 5, the dummy cell transistors DMC11 and DMC12 are adjusted to have a threshold voltage of about 0.6V and the dummy cell transistors DMC21 and DMC22 are adjusted to have a threshold voltage of about −2V, a related bias voltage applied to respective parts of the circuit in the read operating mode can be described as follows.

After a read command is applied, at a time point t1, 0.7V is applied to the selected bit line BLe and a power supply voltage Vcc of about 2.6V is applied to non-selected bit line BLo, as shown in the right graph of FIG. 6. At a time point t2, a power supply voltage Vcc is applied to a string selection line SSL. (generally, read voltage Vread was applied to the SSL.) Also, at the time point t2, a selection read voltage Vread is applied to a selected-word line, i.e., WL0. A control voltage Dummy2 is applied as the read voltage Vread, and control voltage Dummy1 is applied as about 1V. At this point, the dummy cell transistor DMC22 is turned ON, and the dummy cell transistor DMC11 is turned OFF, electrically isolating the second cell string 20b from the bit line BLo. On the other hand, the dummy cell transistors DMC12 and DMC21 in selected-cell string 20a are both turned ON, and a channel of the selected memory cell transistor MC0a is electrically connected between bit line BLe and the common source line CSL. That is, the first cell string 20a has a discharge path, while a discharge path of the second cell string 20b is cut off and so enters a floating state.

Each channel of the non-selected memory cells of the non-selected bit line BLo is precharged to a voltage corresponding to Vcc-Vth (the threshold voltage of SST2) after the time point t2, through the bias condition Bias discussed above. In this state, when read voltage Vread is applied to non-selected word lines WL1-WL31 and a ground selection line GSL at a time point t3, a channel voltage increase appears by a self-boosting operation.

Consequently, as the channel voltage of the non-selected memory cells connected to the non-selected bit line is self-boosted by the read voltage Vread, it appears as a boosting voltage Vboost increased by a boosting ratio in Vcc-Vth. The boosting ratio depends primarily on a coupling ratio of the memory cell transistor, which indicates a rate of capacitance between a second capacitance (C2) between a control gate (CG) and a floating gate (FG) and a first capacitance (C1) between the FG and a bulk/substrate. The coupling ratio Cr may be represented as C2/(C1+C2). In an embodiment of the present invention, the coupling ratio Cr is 0.5, and memory cell transistors have a threshold voltage of about −3V in an erase state. In the bias voltage waveforms of FIG. 6, the time points t1 and t2 were indicated as distinct times only for convenience of explanation. There is no particular difference in operating results even in a simultaneous bias occurrence.

The non-selected memory cell transistors connected to the non-selected bit line have much less electrical stress as compared to general non-selected memory cell transistors due to the channel voltage being increased by self-boosting. Thus, read disturbance can be prevented or substantially reduced, lowering the possibility of occurrences of read error.

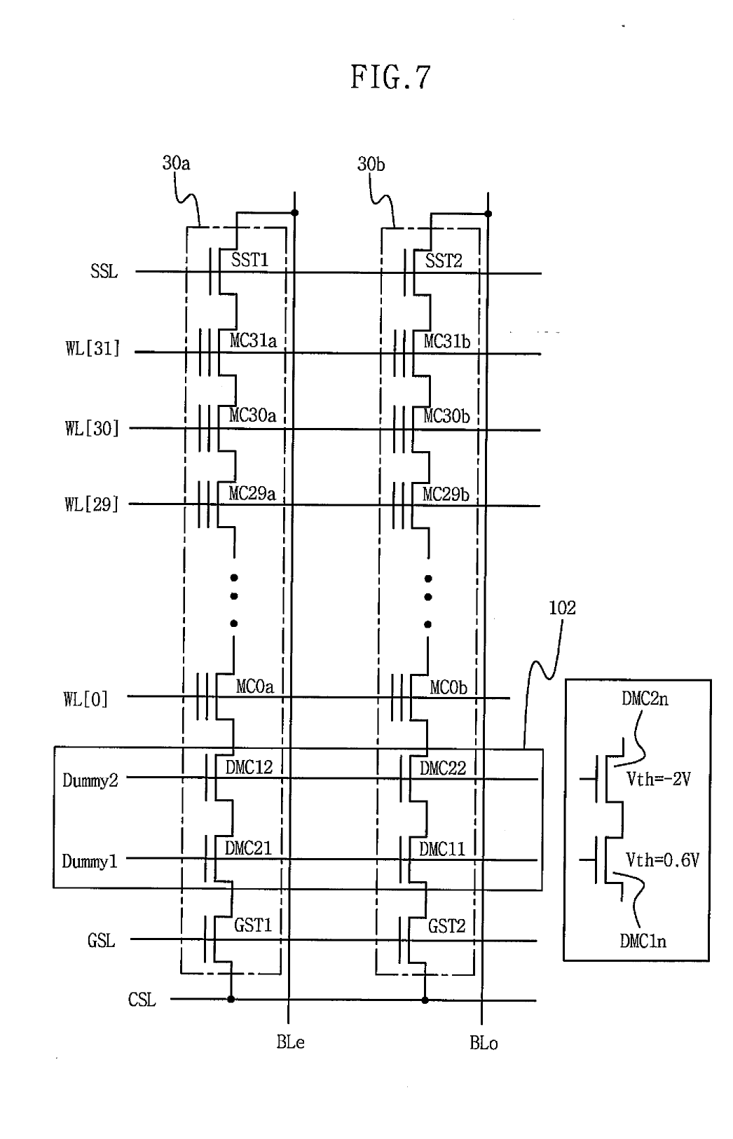

FIG. 7 is a circuit diagram of an equivalent circuit illustrating another embodiment of FIG. 4. Unlike FIG. 5, the example in FIG. 7 provides a dummy transistor unit 102 that includes dummy transistors DMC11, DMC12, DMC21 and DMC22 that may be general transistors, such as a string selection transistor SST or a ground selection transistor GST. In other words, the dummy transistor unit 102 is configured as a general MOS transistor, not as a memory cell transistor having a floating gate. As in FIG. 5, each of the dummy cell transistors DMC11 and DMC12 are controlled to have a threshold voltage of about 0.6V, and each of the dummy cell transistors DMC21 and DMC22 are controlled to have a threshold voltage of about −2V.

In FIG. 7, the correlation of bias voltage applied to respective parts of the circuit in a read operating mode is the same as that of FIG. 6. Therefore, the only practical difference is that the floating formation switching unit (e.g., 110 and 120 in FIG. 4) is constructed of transistors, such as string selection transistors, instead of memory cell transistors. Otherwise, it is the same with respect to the channel voltage for non-selected memory cells connected to a non-selected bit line being increased by a self-boosting operation.

FIG. 8 illustrates voltage stress in a non-selected memory cell coupled to a non-selected bit line, shown in FIG. 4. A channel voltage Vch between a source 12 and a drain 14 exceeds about 4V by the self-boosting effect. As compared to the general memory cell transistor MCib of FIG. 3, for example, in which an electrical field of about 6 MV/cm is applied to the gate insulation layer 16, an electrical field of about 1 MV/cm is applied in an embodiment of the present invention. In FIG. 8 indicates this comparison by an arrow ARI, which shows the difference in electrical field strength.

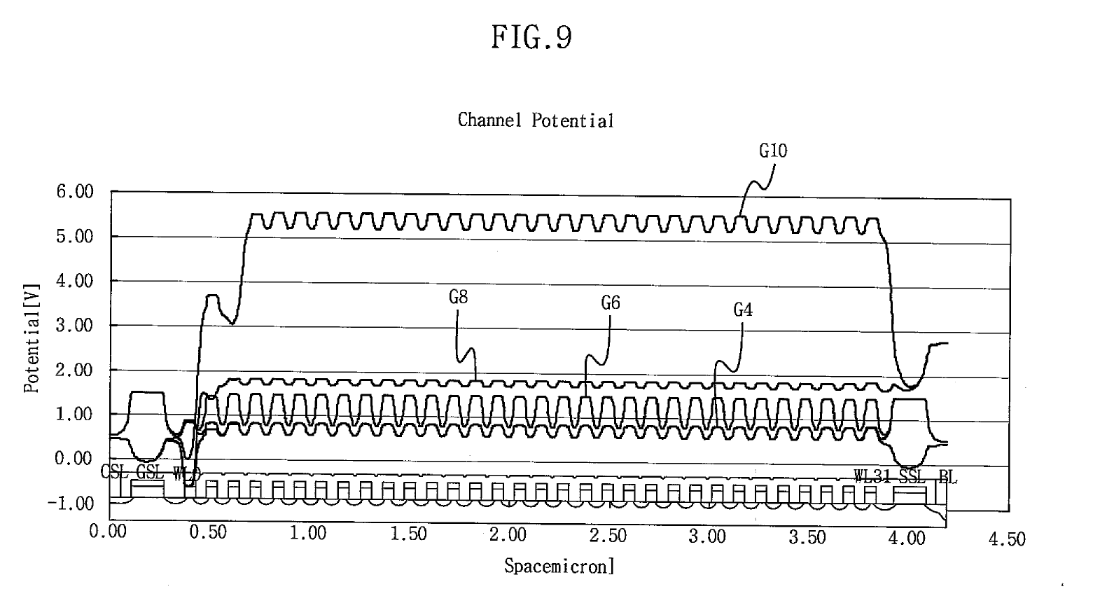

FIG. 9 provides a graph of simulation illustrating a channel voltage boosting effect to prevent a read disturbance in the connected structure of FIG. 4. In FIG. 9, a transverse axis indicates one cell string having 32 memory cell transistors in microns, and a longitudinal axis indicates a channel voltage of non-selected memory cell transistors connected to a non-selected bit line in volts. A comparison of graph G10 with graph G6 clearly discriminates between an embodiment of the invention that prevents read disturbance and a general case that causes a read disturbance. Consequently, a channel voltage between a drain and a source shown in the graph G10 indicates over about 5V with respect to the example embodiment, which is higher than the general example by about 4V. Graph G8 indicates a channel voltage precharged before a self-boosting operation, according to an embodiment of the invention. Graph G4 synthetically indicates a general initial operation and operation after an applied power supply voltage, and a channel voltage based on an initial operation according to an embodiment of the invention.

As described above, non-selected memory cell transistors in a non-selected cell string perform a self-boosting operation in a read operating mode, thus the channel voltage of each of the non-selected memory cell transistors increases, as illustrated in FIG. 9. Therefore, the electrical stress applied to a gate insulation layer 16 of the non-selected memory cell transistors MC31b, MC30b, . . . , MC1b, that is, the electrical field, is less than about 1.0 MV/cm, as shown in FIG. 8, thereby substantially reducing or preventing read disturbances.

A nonvolatile memory device having the configuration of a memory cell array shown in FIG. 5 or FIG. 7 may also include an erase circuit for performing an erase operation, returning a data maintenance characteristic of the memory cells to an initial state, for example, in the control circuit 7 of FIG. 1. Further, the nonvolatile memory device may include a program circuit for storing data in the normal memory cells that have undergone the erase operation, for example, in the control circuit 7 of FIG. 1.

As described above, read disturbances of non-selected memory cell transistors coupled to a non-selected bit line can be prevented or substantially reduced in a read operating mode by employing dummy cell unit 100. That is, a probability of a read error occurrence in a read operation of memory cell is reduced.

Referring to FIGS. 10 to 17, more efficiently adjusting threshold voltages of dummy cells, according to illustrative embodiments of the invention, is described as follows.

FIG. 10 is a block diagram schematically illustrating a nonvolatile semiconductor memory device, according to exemplary embodiments of the present invention. FIG. 10 shows a block connection configuration of a NAND type flash memory, including a memory cell array 1 having dummy cells within a cell string, a sense amplifier and latch 2 for sensing and storing input/output data of memory cell transistors within the memory cell array 1, a column decoder 3 for selecting bit lines, an input/output buffer 4, a row decoder 5 for selecting word lines, an address register 6, a high voltage generating circuit 8 for generating a high voltage higher than a power supply voltage, a control circuit 7 for controlling operations of the nonvolatile semiconductor memory device. A dummy cell controller 101 is coupled to the control circuit 7, for adjusting a threshold voltage of the dummy cells provided within the memory cell array 1.

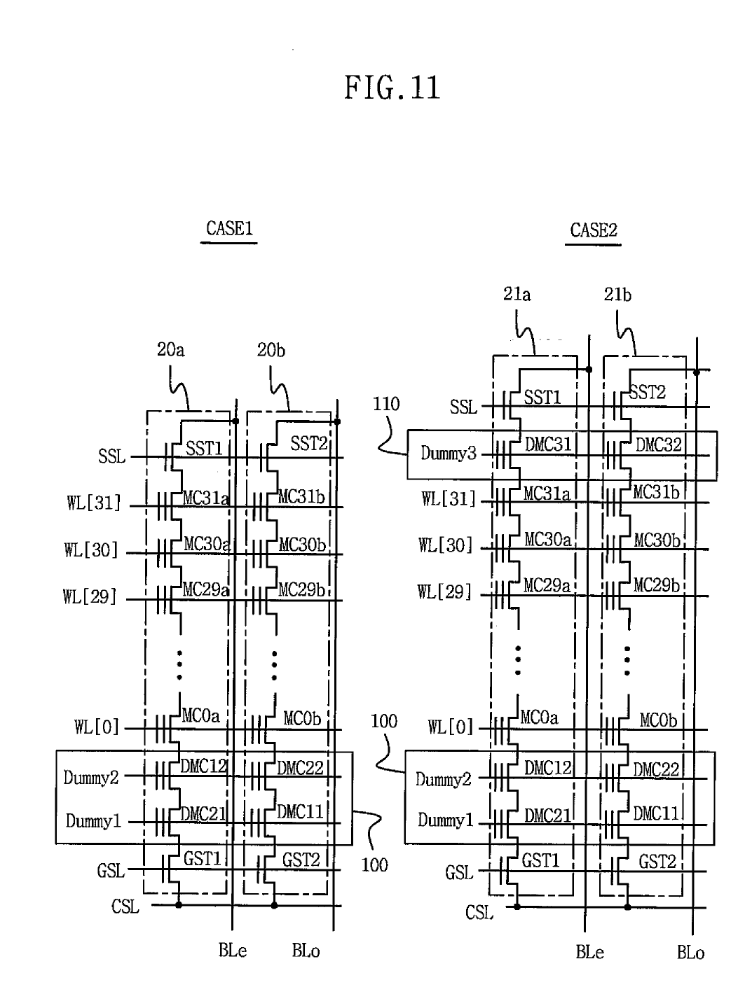

As shown in the circuit diagram of FIG. 11, in an optional cell string 20a of the memory cell array 1, dummy cells DMC12 and DMC21 having mutually different threshold voltage values are configured to prevent a read disturbance in normal memory cells MC0a-MC31a. Of course, the dummy cells DMC12 and DMC21 may be employed for storing specific data or other usages beyond prevention of read disturbance.

Die-sorting and repairing the semiconductor memory chip is performed at a wafer level after fabricating multiple semiconductor memory chips on a wafer, which includes the memory cell array. The dummy cell controller 101 performs a threshold voltage adjustment for the dummy cells, e.g., in response to an external input command before performing die-sorting and repair (or redundancy) of the normal memory cells. Further, the dummy cell controller 101 may perform die-sorting and repair for the dummy cells before the threshold voltage of the dummy cells is controlled.

FIG. 11 illustrates cell string structures having two or more dummy cells per cell string within the memory cell array shown in FIG. 10. The connection structure example of cell strings shown in the left side of FIG. 11 is hereinafter referred to as case 1, and the connection structure example of cell strings shown in the right side of FIG. 11 is hereinafter referred to as case 2. In case 1, two dummy cells are connected per one cell string, and in case 2, three dummy cells are connected per one cell string.

In case 1, first and second cell strings 20a and 20b, which constitute a portion of memory cell array 1 of FIG. 10, have essentially the same structure as the cell string structure of FIG. 5, for example. In comparison, in case 2, first and second cell strings 21a and 21b, which constitute a portion of memory cell array 1 of FIG. 10, have a structure in which fifth selection transistors DMC31 and DMC32 functioning as a dummy cell have been added to the connection construction of the case 1.

In other words, in case 2, the first cell string 21a includes a first selection transistor SST1 having a drain coupled to a bit line BLe, a fifth selection transistor DMC31 having a drain coupled to a source of the first selection transistor SST1, a second selection transistor GST1 having a source coupled to a common source line CSL, and multiple memory cell transistors MC31a, MC30a, . . . , and MC0a having channels mutually connected in series to a source of the fifth selection transistor DMC31 and each having a floating gate. The first cell string 21a also includes third and fourth selection transistors DMC12 and DMC21 having channels connected in series to each other between a source of the memory cell transistor MC0a, located farthest from the bit line BLe among the memory cell transistors MC31a, MC30a, . . . and MC0a, and a drain of the second selection transistor GST1. The third and fourth selection transistors DMC12 and DMC21 have mutually different threshold voltage values.

For example, within the dummy cell unit 100 constituting floating formation switching units, the dummy cell transistors DMC11 and DMC12 are determined to have a threshold voltage of about 0.6V to 2V, and the dummy cell transistors DMC21 and DMC22 are determined to have a threshold voltage of about −2V. Thus, when the second cell string 21b is not selected, and control voltage Dummy2 is applied as a read voltage Vread and control voltage Dummy1 is applied as about 1V, the dummy cell transistor DMC11 is turned off even though the dummy cell transistor DMC22 is turned on. Therefore, the common source line CSL is not electrically coupled to the bit line BLo through the second cell string 21b. Meanwhile, the dummy cell transistors DMC12 and DMC21 of the selected cell string 21a are all turned on, thereby providing a condition to normally perform a read operation of a selected memory cell transistor.

Dummy cell unit 110, which includes fifth selection transistors DMC31 and DMC32, is employed for an edge effect of word line WL[31].

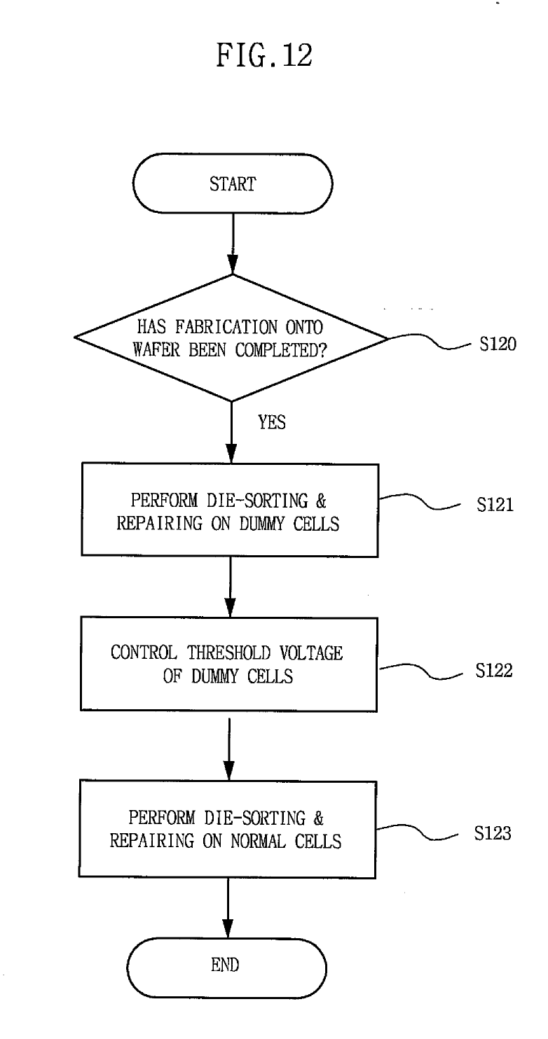

FIG. 12 is a flowchart illustrating a related sequence of die-sorting and repairing for dummy cells and normal memory cells when fabrication of the device of FIG. 10 onto a wafer is completed, according to exemplary embodiments of the present invention.

Referring to FIG. 12, steps S120 to S123 are provided sequentially. In step S120, it is determined whether fabrication onto a wafer has been completed. For example, the nonvolatile memory device of FIG. 10, having dummy cells within a cell string as shown in FIG. 11, is fabricated as one of multiple chips on a wafer. In an embodiment, when fabrication of the nonvolatile memory device onto the wafer is completed, the dummy cells are processed earlier than normal memory cells in an Electrical Die-sorting (EDS) process. Consequently, after fabricating multiple semiconductor memory chips on the wafer, die-sorting and repairing the semiconductor memory chips at a wafer level may be selectively performed at step S121. Step S121 primarily performs die-sorting and repair for the dummy cells provided within the cell string.

When step S121 is selectively completed, step S122 is performed to adjust a threshold voltage for the dummy cells. Secondary die-sorting and repair is then performed for normal memory cells provided within the cell string at step S123.

In FIG. 12, in die-sorting and repairing the semiconductor memory chip at the wafer level, a threshold voltage adjusting for the dummy cells is performed in response to an externally input command, for example, before performing die-sorting and repair for the normal memory cells. Thus, the threshold voltage adjusting for dummy cells is performed separately from that of normal memory cells. The process depicted in FIG. 12 is controlled by dummy cell controller 101 in response to an input command ICMD, as shown in FIG. 10. The input command ICMD is a signal generated by the control circuit 7 when an external tester inputs an external input command to the control circuit.

According to another illustrative embodiment of the invention, a threshold voltage of dummy cells may be adjusted at a user level, after nonvolatile semiconductor memory devices go on the market within products.

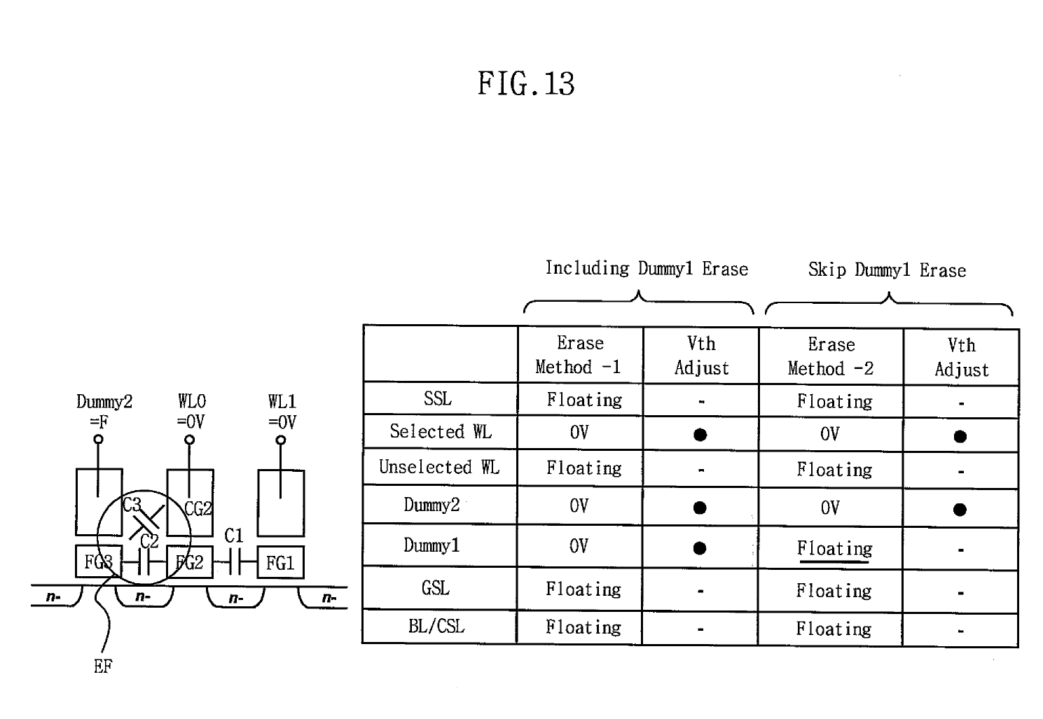

FIG. 13 illustrates a related bias voltage of erase operations in a block erase of memory cells shown in FIG. 11.

As shown in FIG. 13, a coupling issue EF caused by a parasitic capacitance C3 may be produced in the block erase operation. The coupling issue involves an erase error occurring in a memory cell MC0a of a cell string in FIG. 11, for example. In the memory cell MC0a, which is positioned farthest from bit line BLe, an insufficient erase operation may be generated due to the coupling issue. It is therefore difficult to accurately adjust to a threshold voltage determined in the erase operation, so the memory cell MC0a has a higher threshold voltage value as compared with adjacent memory cell MC1a, for example. To solve the erase error problem, in accordance with an embodiment of the present invention, a control voltage Dummy2 of adjacent dummy cell DMC12 is applied as 0V. Also, a control voltage Dummy1 of remaining (non-adjacent) dummy cell DMC21, coupled between the adjacent dummy cell DMC12 and a ground selection transistor GST1, is applied as one of two possibly voltages. That is, the control voltage Dummy1 of dummy cell DMC21 may be applied as 0V or maintained in a floating state. The table shown in FIG. 13 represents an erase operation bias voltage relation based on the two voltages.

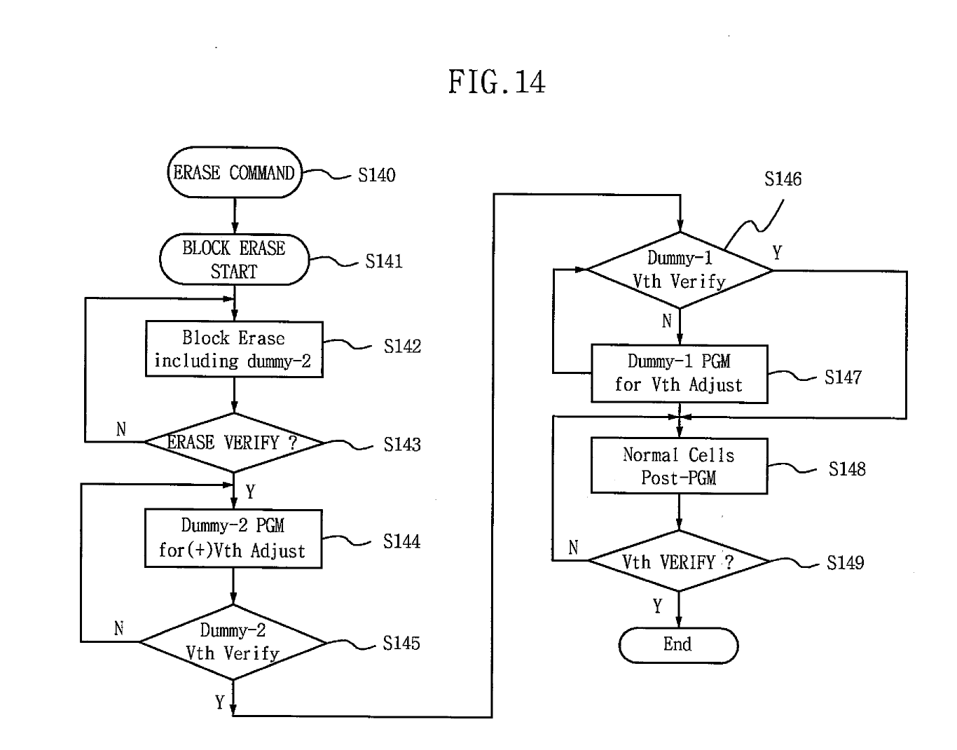

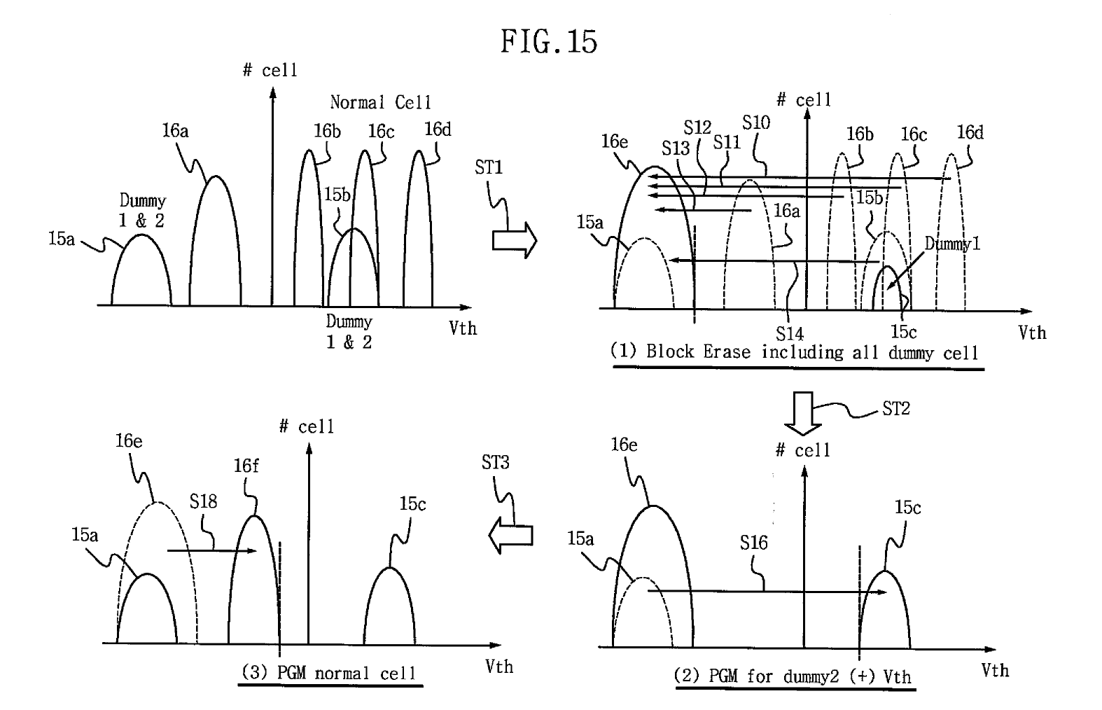

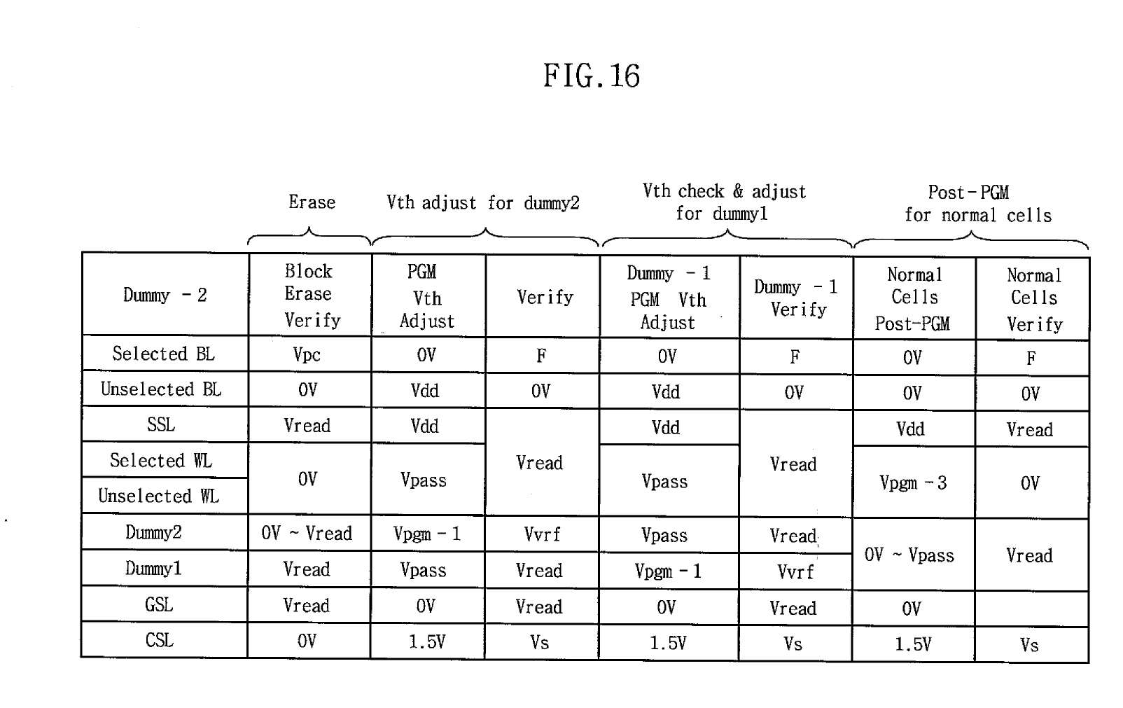

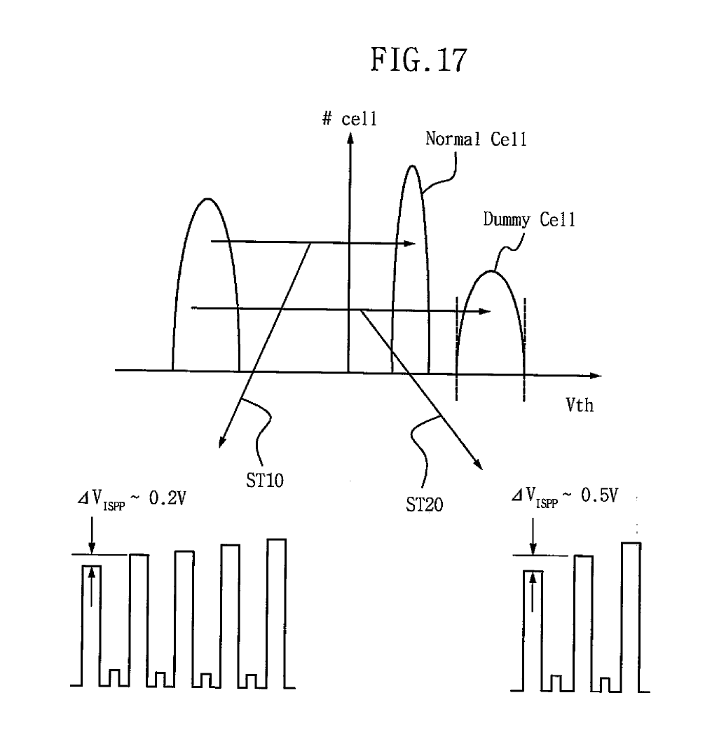

FIG. 14 is a flowchart illustrating a sequence of a program operation for dummy cells and a block erase operation referred to in FIG. 13, according to exemplary embodiments of the present invention. FIG. 15 illustrates distribution changes of a threshold voltage for cell transistors, according to an operation sequence of FIG. 14. FIG. 16 is a table illustrating related operation bias voltages, individually applied according to the operation sequence of FIG. 14. FIG. 17 comparatively illustrates a step increasing width of incremental step-pulse program for a dummy cell and a normal cell in a program operation of FIG. 14.

Referring first to FIG. 14, steps S140 to S149 are provided sequentially. An erase command is received in step S140 and a block erase operation begins in step S141. In step S142, the block erase operation is performed, including an adjacent dummy cell. Erase bias voltages, shown in the right side of the table in FIG. 13, are applied to a cell string of FIG. 11 in step S142. For example, string selection line SSL, non-selected word lines, control voltage Dummy1 of dummy cell DMC21, ground selection line GSL, and bit line/common selection line BL/CSL are biased in a floating state. Control voltage Dummy2 of adjacent dummy cell DMC12 and selected word line are biased as a ground voltage, i.e., 0V.

When step S142 is completed, an erase verify operation is performed in step S143. The erase verify operation determines whether a threshold voltage of the normal memory cells became a threshold voltage value after the erase. Thus, the erase verify operation of step S143 is performed for normal memory cells of the cell string, and control voltage Dummy2 of adjacent dummy cell DMC12 is applied as 0V to read voltage Vread like a bias voltage, shown in the erase verify section of the table in FIG. 16. Control voltage Dummy1 of dummy cell DMC21 is applied as read voltage Vread. In this case, the erase verify voltage is applied to a selected bit line, and 0V is applied to non-selected bit lines and selected/non-selected word lines. Also as shown in the block erase verify column of the table in FIG. 16, the string selection line SSL and the ground selection line GSL are biased as read voltage Vread, and the common selection line CSL is biased as 0V.

Upon completion of step S143, normal memory cells and dummy memory cells within the memory cell array have a state transition ST1, as shown in FIG. 15. In other words, the normal memory cells and the dummy memory cells have cell distributions indicated by the transition from the upper left graph of FIG. 15 to the upper right graph of FIG. 15. That is, when the normal memory cells are multilevel cells MLC, they have four distributions 16a, 16b, 16c and 16d before the erase operation, and the dummy cells have two distributions 15a and 15b before the erase operation. The transverse axis of each graph in FIG. 15 indicates threshold voltages of the cells, and the longitudinal axis indicates the number of cells. In other words, when block erase and verify operations are performed on memory cells in a state as shown in the upper left graph of FIG. 15, the state transition ST1, indicated by an arrow, is generated and the cell distribution changes to a state as shown in the upper right graphs of FIG. 15.

The four distributions 16a, 16b, 16c and 16d for the normal cells move along arrows S10, S11, S12 and S13, respectively, to be integrated as one distribution 16e. In other words, according to the erase operation, all normal memory cells have a threshold voltage value of about −3V, for example. Adjacent dummy cells among the dummy cells move along an arrow S14 of the upper right graph of FIG. 15, and are included in distribution 15a. All dummy cells, including remaining dummy cell DMC21 and dummy cells in the same relative position as the remaining dummy cell DMC21, remain in distribution 15c.

Referring again to FIG. 14, when step S143 is completed, all adjacent dummy cells within the memory cell array are programmed in step S144 and a program verify operation is performed in step S145. In step S144, in which a program operation is performed for all the adjacent dummy cells, bias voltages are applied as shown in the PGM Vth adjust column of the threshold voltage adjusting section for dummy2 of the table in FIG. 16. For example, a control voltage Dummy2 of adjacent dummy cell DMC12 is applied as a program voltage Vpgm−1, and a control voltage Dummy1 of remaining (i.e., not adjacent) dummy cell DMC21 is applied as a pass voltage Vpass. In this example, 0V is applied to a selected bit line, power voltage Vdd is applied to a non-selected bit line and string selection line SSL, and pass voltage Vpass is individually applied to selected and non-selected word lines. Further, 0V is applied to ground selection line GSL, and about 1.5V is applied to common selection line CSL.

An incremental step-pulse program may be used in the program operation of dummy cells. In this case, a step increasing width of the incremental step-pulse program for dummy cells is larger than a step increasing width of the incremental step-pulse program for normal memory cells, as shown in FIG. 17, for example. That is, in programming dummy cells, an increased voltage level is relatively irregular, and has about 0.5V, as shown in FIG. 17. On the other hand, a step increasing width of normal memory cells is about 0.2V. In FIG. 17, arrow ST20 indicates a step increasing width of the incremental step-pulse program for dummy cells, and arrow ST10 indicates a step increasing width of the incremental step-pulse program for normal memory cells.

Referring back to FIG. 14, in step S145, a program verify operation is performed for all adjacent dummy cells. Bias voltages are applied as shown in the verify column of the threshold voltage adjusting section for dummy2 of the table in FIG. 16.

Upon completion of step S145, normal memory cells and dummy cells within the memory cell array have a state transition ST2, as shown in FIG. 15. In other words, the normal memory cells and the dummy memory cells have cell distributions indicated by the transition from the upper right graph of FIG. 15 to the lower right graph of FIG. 15. The remaining dummy cells among the dummy cells included in the distribution 15a move along arrow S16 and are included in a distribution 15c.

After step S145 of FIG. 14, a program verify operation is performed for remaining dummy cells, which are not adjacent dummy cells, in step S146. Then, a program operation for the remaining dummy cells requiring programming is performed in step S147. In step S146, bias voltages are applied, as shown in the dummy-1 verify column of the threshold voltage Vth check and adjusting for dummy1 section of the table in FIG. 16. In step S147, bias voltages are applied as shown in the dummy-1 PGM column of the threshold voltage Vth check and adjusting section for dummy1 section of the table in FIG. 16.

When the programming of the dummy cells is completed through step S147, a post program operation for normal memory cells is performed in step S148 and a program verify operation is performed in step S149. In step S148, bias voltages are applied as shown in the normal cells post PGM column of the post program for normal cells section of the table in FIG. 16. In the execution of step S148, a threshold voltage value for the normal cells is adjusted to a determined post program target voltage value. In step S149, bias voltages are applied as shown in the normal cells verify column of the post program for normal cells section of the table in FIG. 16.

When step S149 is completed, normal memory cells and dummy memory cells within memory cell array have a state transition ST3, as shown in FIG. 15. In other words, the normal memory cells and the dummy memory cells have cell distributions indicated by the transition from the lower right graph of FIG. 15 to the lower left graph of FIG. 15.

As described above, a semiconductor memory device includes a memory cell array in which at least two dummy cells having different threshold voltages are each included in a cell string. To prevent occurrence of problems, such as read disturbances and the like, for a normal memory cell within the cell string (or for other usage), a sequence of programming the dummy cells before post programming the normal memory cells, includes performing an erase operation for the normal memory cells in cell block units, together with adjacent dummy cells, i.e., nearest the normal memory cells among the dummy cells in the cell string, and then performing an erase verify operation for the normal memory cells. A program operation is performed for all adjacent dummy cells within the memory cell array, followed by a program verify operation. A program verify is performed for the remaining dummy cells, i.e., not adjacent dummy cells, followed by a program operation for all remaining dummy cells requiring programming.

As described above, in a threshold voltage adjusting method for dummy cells, a program operation for dummy cells can be preformed more efficiently, thereby reducing manufacture costs for nonvolatile semiconductor memory devices and increasing convenience and efficiency in programming. In addition, dummy cell functionality can be effectively guaranteed and reliability of an access operation of nonvolatile semiconductor memory devices is enhanced.

While the present invention has been described with reference to exemplary embodiments, it will be apparent to those skilled in the art that various changes and modifications may be made without departing from the spirit and scope of the present invention. For example, the number of transistors constituting a memory cell string or a floating formation switching unit, and the configuration of the device or operating conditions may vary. Accordingly, these and other changes and modifications are seen to be within the spirit and scope of the present invention.

Therefore, it is understood that the above embodiments are not limiting, but illustrative. In the drawings and specification, there have been disclosed typical embodiments of the invention and, although specific terms are employed, they are used in a generic and descriptive sense only and not for purposes of limitation.

What is claimed is:

1. A method of die-sorting and repairing semiconductor memory chips on a wafer, each of the semiconductor memory chips having at least one dummy cell within a cell string, the method comprising:
adjusting a threshold voltage for the at least one dummy cell within the cell string; and
performing die-sorting and repair of normal memory cells within the cell string.

2. The method of claim 1, further comprising:
performing die-sorting and repair of the at least one dummy cell before completing the adjusting of the threshold voltage for the at least one dummy cell.

3. The method of claim 1, wherein the threshold voltage for the at least one dummy cell is adjusted in response to an applied special command different from a normal command.

4. A nonvolatile semiconductor memory device comprising:
a memory cell array on a semiconductor memory chip, the memory cell array comprising at least two dummy cells, having different threshold voltages, and a plurality of normal memory cells within a cell string; and
a dummy cell controller configured to adjust the threshold voltages of the dummy cells in response to an input command before performing a die-sorting and repair operation for the normal memory cells, in die-sorting and repairing the semiconductor memory chip at a level of a wafer, the wafer being fabricated to comprise a plurality of semiconductor memory chips.

5. The device of claim 4, wherein the dummy cell controller further performs a die-sorting and repair operation before adjusting the threshold voltages of the dummy cells.

6. A method of programming dummy cells before post programming normal memory cells in a semiconductor memory device, the semiconductor memory device comprising a memory cell array including a plurality of cell strings, each cell string comprising at least two dummy cells with different threshold voltages and a plurality of normal memory cells, the method comprising:
performing an erase operation for the normal memory cells of each cell string by a cell block unit and for an adjacent dummy cell of the at least two dummy cells, the adjacent dummy cell being closest to the normal memory cells in the cell string, and then performing an erase verify operation for the normal memory cells;
performing a program operation and a program verify operation for the adjacent dummy cell in each cell string of the memory cell array; and
performing a program verify operation for a remaining dummy cell of the at least two dummy cells in each cell string, and then performing a program operation for the remaining dummy cell when the remaining dummy cell requires programming.

7. The method of claim 6, wherein the remaining dummy cell is positioned closer to a ground selection line of the cell string than the adjacent dummy cell.

8. The method of claim 6, wherein in the erase operation of each cell string, a voltage equal to an erase gate voltage, applied to a gate of each of the normal memory cells, is applied to a gate of the adjacent dummy cell, and one of a floating voltage or a voltage higher than the erase gate voltage is applied to a gate of the remaining dummy cell.

9. The method of claim 8, wherein in the erase verify operation of each cell string, one of a ground voltage or a read voltage is applied to the gate of the adjacent dummy cell, and the read voltage is applied to the gate of the remaining dummy cell.

10. The method of claim 8, wherein a step increasing width of incremental step-pulse programming used in the program operation of the dummy cells is predetermined to be greater than a step increasing width of incremental step-pulse programming used in a program operation of the normal memory cells.

11. The method of claim 8, wherein the program operation of the adjacent dummy cells is performed in response to an external input command.

12. The method of claim 8, wherein when there are two dummy cells in each cell string, the adjacent dummy cell is coupled to a normal memory cell positioned farthest from a corresponding bit line and the remaining dummy cell is coupled to a ground selection transistor.

13. The method of claim 8, wherein when there are three dummy cells in each cell string, the adjacent dummy cell is coupled to a normal memory cell positioned farthest from a bit line, and the remaining dummy cells are respectively coupled to a ground selection transistor and a string selection transistor.
